(19) United States
(12) Patent Application Publication
(10) Pub. No.: US 2016/0276282 A1
(43) Pub. Date: Sep. 22, 2016

(54) SEMICONDUCTOR DEVICE AND METHOD FOR MANUFACTURING SAME

(71) Applicant: Kabushiki Kaisha Toshiba, Minato-ku (JP)

(72) Inventor: Masayoshi TAGAMI, Kuwana (JP)

(73) Assignee: Kabushiki Kaisha Toshiba, Minato-ku (JP)

(21) Appl. No.: 14/838,825

(22) Filed: Aug. 28, 2015

Related U.S. Application Data
(60) Provisional application No. 62/135,409, filed on Mar. 19, 2015.

(51) Int. Cl. H01L 23/532; H01L 23/522; H01L 21/768; H01L 27/115

(52) U.S. Cl. CPC H01L 23/53295; H01L 27/11524; H01L 23/5226; H01L 21/76883; H01L 21/76802

(57) ABSTRACT

A semiconductor device includes a semiconductor layer, a first insulating film provided on the semiconductor layer, a second insulating film provided on the first insulating film and including a material different from a material of the first insulating film, a first interconnect extending in a first direction along a surface of the semiconductor layer on the second insulating film, a second interconnect disposed side by side with the first interconnect on the second insulating film, and a third insulating film covering the first interconnect and the second interconnect, the third insulating film including a first gap between the first interconnect and the second interconnect. An upper surface of the second insulating film directly below the first gap is located at a level equal to or below a lower end of the first interconnect and a lower end of the second interconnect.

### CROSS-REFERENCE TO RELATED APPLICATIONS

This application is based upon and claims the benefit of priority from U.S. Provisional Patent Application 62/135,409 filed on Mar. 19, 2015; the entire contents of which are incorporated herein by reference.

### FIELD

Embodiments described herein relate generally to a semiconductor device and a method for manufacturing the same.

### BACKGROUND

The interconnect spacing inside a semiconductor device becomes narrower with the increase of its degree of integration. This causes concern about the decrease of operating speed due to the increase of interconnect capacitance. For instance, large-scale integration of memory cells in a NAND non-volatile memory device makes narrower the spacing between bit lines electrically connecting the memory string with the sense amplifier. Thus, it is desirable to form a gap between the bit lines to reduce the capacitance between the interconnects. However, it is difficult to form a gap with a uniform depth between miniaturized bit lines.

### BRIEF DESCRIPTION OF THE DRAWINGS

FIGS. 1A and 1B are schematic sectional views showing a semiconductor device according to a first embodiment;

FIGS. 2A to 2F are schematic sectional views showing a process for manufacturing the semiconductor device according to the first embodiment;

FIGS. 3A to 3E are schematic sectional views showing a process for manufacturing a semiconductor device according to a comparative example;

FIG. 4 is a schematic sectional view showing a semiconductor device 300 according to a second embodiment; and

FIGS. 5A to 5F are schematic sectional views showing a process for manufacturing the semiconductor device according to the second embodiment.

### DETAILED DESCRIPTION

According to one embodiment, a semiconductor device includes a semiconductor layer, a first insulating film provided on the semiconductor layer, a second insulating film provided on the first insulating film and including a material different from a material of the first insulating film, a first interconnect extending in a first direction along a surface of the semiconductor layer on the second insulating film, a second interconnect disposed side by side with the first interconnect on the second insulating film, and a third insulating film covering the first interconnect and the second interconnect, the third insulating film including a first gap between the first interconnect and the second interconnect. An upper surface position of the second insulating film directly below the first gap is located at a level equal to or below a lower end of the first interconnect and a lower end of the second interconnect.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

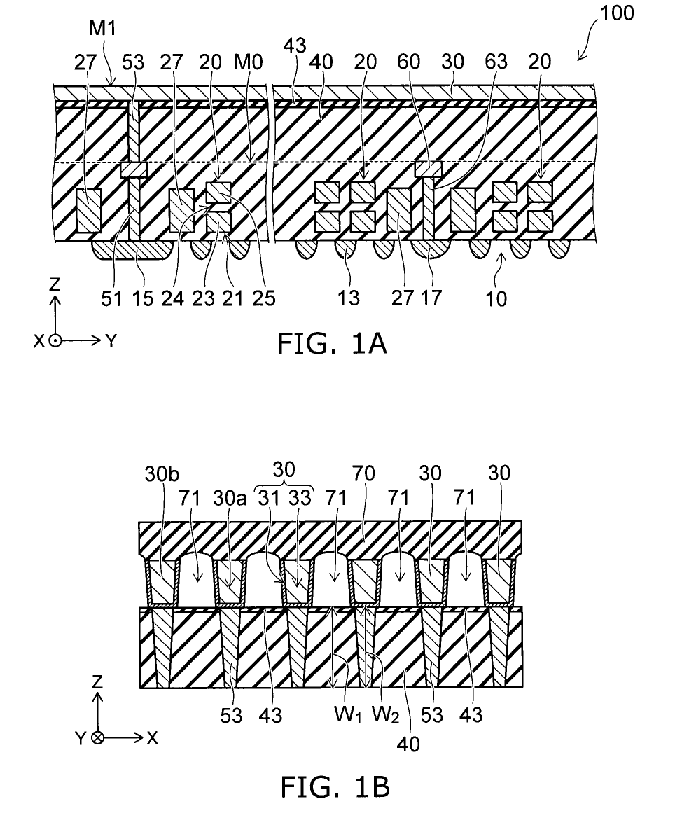

FIGS. 1A and 1B are schematic sectional views showing a semiconductor device 100 according to a first embodiment. The semiconductor device 100 is e.g. a NAND flash memory. FIG. 1A is a schematic view showing the Y-Z cross section of the semiconductor device 100. FIG. 1B is a schematic view showing the X-Z cross section of the semiconductor device 100.

As shown in FIG. 1A, the semiconductor device 100 includes a semiconductor layer 10, a plurality of memory cells 20 provided on the semiconductor layer 10, and a select gate 27. The plurality of memory cells 20 are disposed side by side on the semiconductor layer 10. The select gates 27 are provided on both sides of the plurality of memory cells 20. Each memory cell 20 includes a floating gate 23 and a control gate 25. The floating gate 23 is provided via a tunnel insulating film 21 on the semiconductor layer 10. The control gate 25 is provided via a block insulating film 24 on the floating gate 23.

The semiconductor layer 10 is made of e.g. p-type semiconductor. The semiconductor layer 10 includes a source/drain region 13, a drain region 15, and a source region 17. The source/drain region 13, the drain region 15, and the source region 17 are n-type regions provided in the surface of the semiconductor layer 10. The source/drain region 13 is provided between the adjacent memory cells 20 and between the memory cell 20 and the select gate 27.

Thus, the semiconductor device 100 includes a NAND string. The NAND string includes a plurality of memory cells 20 and select gates 27 disposed on the semiconductor layer 10. A plurality of bit lines 30 are disposed via a first insulating film (interlayer insulating film 40) above the NAND memory string. Each bit line 30 extends in a first direction (hereinafter, Y-direction) along the surface of the semiconductor layer 10.

The example shown in FIG. 1A includes a second insulating film (hereinafter, insulating film 43) between the interlayer insulating film 40 and the bit line 30. The insulating film 43 is provided on the interlayer insulating film 40. The bit line 30 is provided on the insulating film 43. The bit line 30 is included in an interconnect layer M1.

As shown in FIG. 1A, the bit line 30 is electrically connected to the semiconductor layer 10 through contact plugs 51 and 53. The contact plug 51 extends in a second direction (hereinafter, Z-direction) in the interlayer insulating film 40.

The contact plug 51 is provided between the semiconductor layer 10 and an intermediate interconnect layer M0. One end of the contact plug 51 is in contact with the drain region 15 provided in the semiconductor layer 10. Thus, the contact plug 51 is electrically connected to one end of the NAND string. The select gate 27 is disposed between the contact plug 51 and the plurality of memory cells 20.

The contact plug 53 is provided between the interconnect layer M0 and the interconnect layer M1. The contact plug 53 extends in the Z-direction in the interlayer insulating film 40. One end of the contact plug 53 is connected to the bit line 30. The other end of the contact plug 53 is electrically connected to the contact plug 51.

A source line 60 is electrically connected to the other end of the NAND string through a contact plug 63. The source line 60 is included in the interconnect layer M0. The source line 60 extends in the X-direction in the interlayer insulating film 40. One end of the contact plug 63 is in contact with the source region 17. The other end of the contact plug 63 is in contact with the source line 60. Another select gate 27 is disposed between the contact plug 63 and the plurality of memory cells 20.

FIG. 1B is a schematic view showing the X-Z cross section including the contact plug 53. FIG. 1B shows a portion of the interlayer insulating film 40 above the interconnect layer M0, the bit line 30, and a third insulating film (hereinafter, insulating film 70).

The bit line 30 is provided on each contact plug 53. The bit line 30 includes e.g. a barrier layer 31 and a conductive layer 33. The barrier layer 31 is e.g. a titanium nitride layer. The barrier layer 31 is in contact with the contact plug 53. The conductive layer 33 is e.g. a metal layer including copper (Cu). The conductive layer 33 is provided on the barrier layer 31. The barrier layer 31 suppresses diffusion of metal atoms from the conductive layer 33 to the interlayer insulating film 40.

The plurality of bit lines 30 include first interconnects (hereinafter, bit lines 30a) and second interconnects (hereinafter, bit lines 30b). The bit line 30b is disposed side by side with the bit line 30a adjacent in the X-direction.

The insulating film 70 straddles the adjacent bit lines 30 and provides a gap 71 between the adjacent bit lines 30. The gap 71 extends in the Y-direction along the bit line 30. Directly below the gap 71, the insulating film 43 is located at the same level as the lower end of the bit line 30a and the lower end of the bit line 30b. In other words, the spacing W₁ between the upper surface of the insulating film 43 and the interconnect layer M0 is nearly equal to the spacing W₂ between the lower end of the bit line 30 and the interconnect layer M0. Thus, the gap 71 can have nearly the same height (Z-direction width) as the height from the upper end to the lower end of the bit line 30. This can reduce parasitic capacitance between the adjacent bit lines 30.

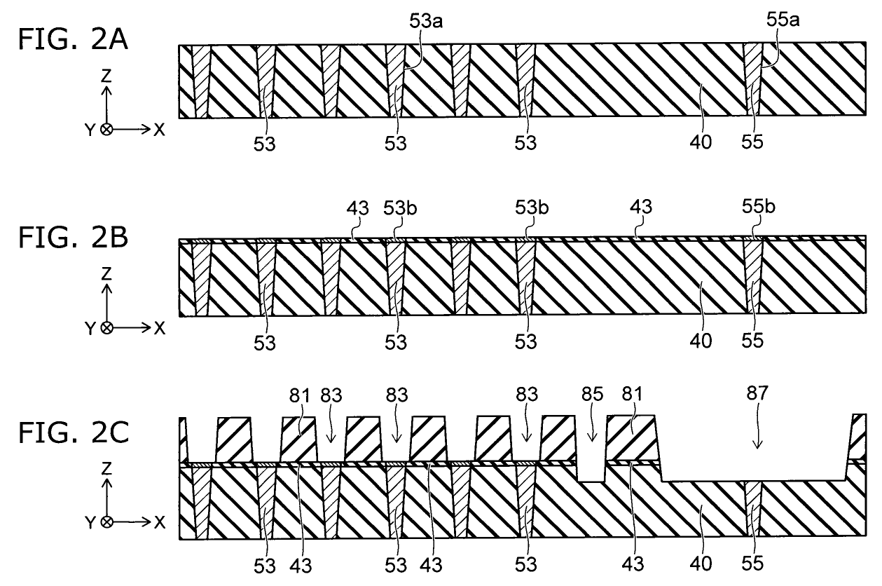

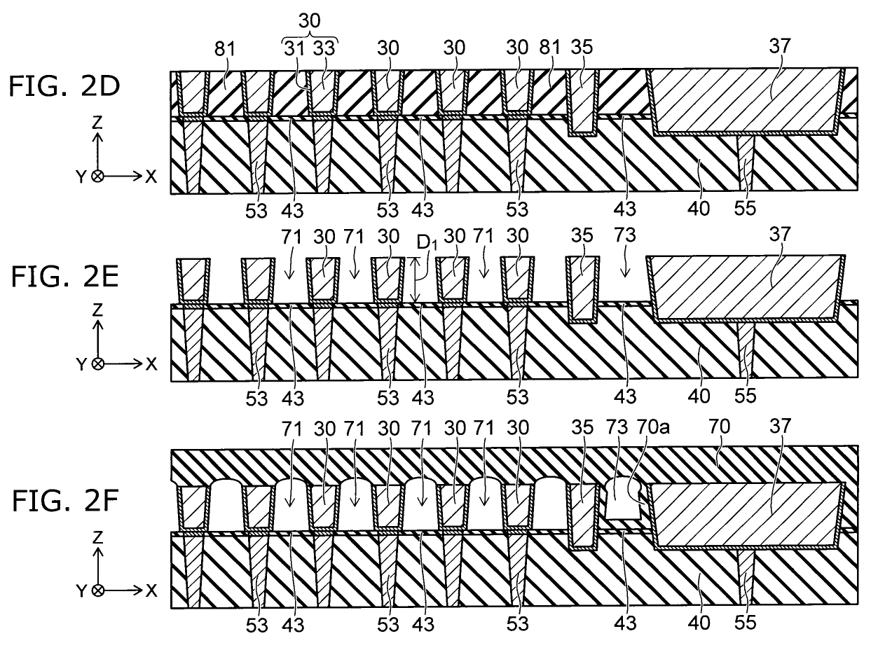

Next, a method for manufacturing the semiconductor device 100 is described with reference to FIGS. 2A to 2F. FIGS. 2A to 2F are schematic sectional views showing a process for forming the bit lines 30.

As shown in FIG. 2A, in the memory area in which the memory cells 20 are disposed, a contact plug 53 is formed in the interlayer insulating film 40. Specifically, an interlayer insulating film 40 covering the semiconductor layer 10, the memory cells 20, and the select gates 27 is formed, and a contact hole 53a is formed in the interlayer insulating film 40. The interlayer insulating film 40 is e.g. a silicon oxide film. A contact hole 55a is simultaneously formed also around the memory area.

Next, a metal layer such as a tungsten layer covering the interlayer insulating film 40 is formed and buried inside the contact holes 53a and 55a. Next, the metal layer on the interlayer insulating film 40 is removed by CMP (chemical mechanical polishing). Thus, contact plugs 53 and 55 are formed inside the contact holes 53a and 55a.

As shown in FIG. 2B, an insulating film 43 is formed by reforming the surface of the interlayer insulating film 40. The insulating film 43 is e.g. a silicon nitride film. The insulating film 43 can be formed by e.g. supplying plasma-excited nitrogen radicals to the surface of the interlayer insulating film 40 to nitridize the interlayer insulating film 40. At this time, nitride films 53b and 55b are formed on the contact plugs 53 and 55, respectively. The nitride films 53b and 55b are made of e.g. tungsten nitride (WN).

As shown in FIG. 2C, a sacrificial film 81 covering the insulating film 43 and the contact plugs 53 and 55 is formed. Then, interconnect grooves 83, 85, and 87 are formed in the sacrificial film 81. In the interconnect groove 83, the sacrificial film 81 is selectively removed to expose the contact plug 53 at the bottom surface thereof. At this time, the nitride film 53b on the contact plug 53 may be removed. Alternatively, part of the nitride film 53b on the contact plug 53 may be left.

The interconnect grooves 85 and 87, for instance, are formed around the memory area. The interconnect grooves 85 and 87 are formed by selectively removing the sacrificial film 81 and the insulating film 43 so that the bottom surface thereof is located in the interlayer insulating film 40.

As shown in FIG. 2D, a metal layer is buried inside the interconnect grooves 83, 85, and 87 to form bit lines 30 and interconnects 35, 37. For instance, a TiN layer and a Cu layer covering the sacrificial film 81 and the interconnect grooves 83, 85, and 87 are sequentially formed. Next, the TiN layer and the Cu layer on the sacrificial film 81 are removed by e.g. CMP. Thus, bit lines 30 and interconnects 35, 37 are formed inside the interconnect grooves 83, 85, and 87.

As shown in FIG. 2E, the sacrificial film 81 is removed. For instance, the sacrificial film 81 is selectively removed by RIE (reactive ion etching). At this time, the sacrificial film 81 is removed using an etching condition such that the etching rate of the sacrificial film 81 is faster than the etching rate of the insulating film 43. Thus, the insulating film 43 is exposed. Accordingly, a gap 71 having a uniform depth (Z-direction width D₁) can be formed between the adjacent bit lines 30 by causing the insulating film 43 to function as an etching stopper.

As shown in FIG. 2F, an insulating film 70 is formed on the bit lines 30 and the interconnects 35 and 37. The insulating film 70 is formed so as to occlude the top of the gap 71 between the adjacent bit lines 30. The insulating film 70 is e.g. a silicon oxide film formed by plasma CVD (plasma enhanced chemical vapor deposition).

In the case of using plasma CVD, a thicker insulating film can be formed on the upper surface of the bit line 30 than on the inner surface of the gap 71. Thus, an insulating film 70 straddling the adjacent bit lines 30 can be formed before the gap 71 is buried. For instance, for a narrow spacing between the adjacent bit lines 30, the insulating film 70 can be formed without forming an insulating film on the inner surface of the gap 71. Here, a thin insulating film, which is part of the insulating film 70, may be formed on the inner surface of the gap 71. In the example shown in FIG. 2F, the gap 73 between the interconnects 37 has a wider X-direction width than the gap 71. For instance, an insulating film 70a is formed on the inner surface of the gap 73.

The embodiment has illustrated a method for forming an insulating film 43 by reforming the surface of the interlayer insulating film 40. However, the embodiment is not limited thereto. For instance, after forming an insulating film 43 on the interlayer insulating film 40, contact holes 53a and 55a may be formed, and contact plugs 53 and 55 may be buried therein.

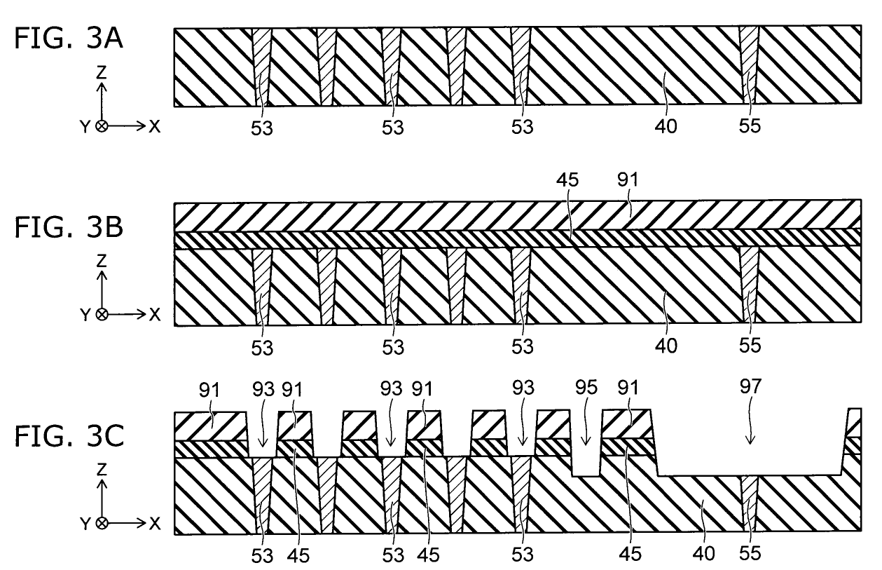

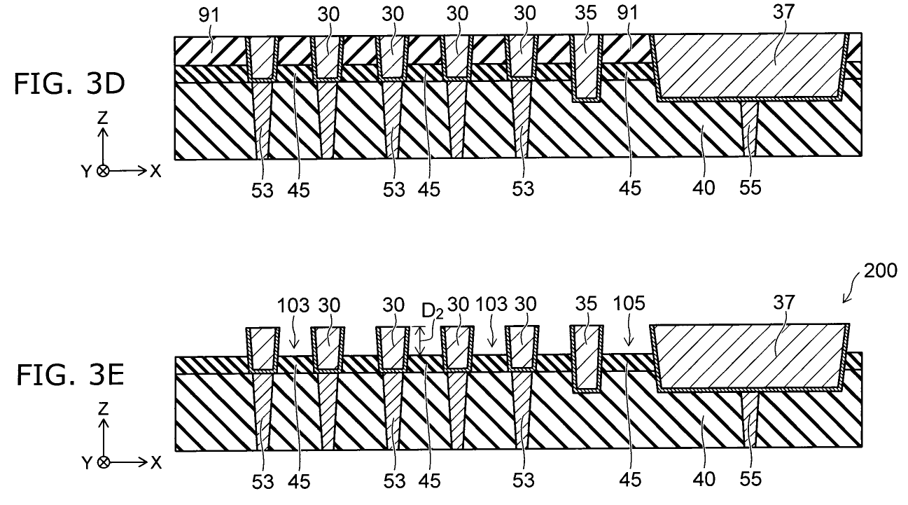

FIGS. 3A to 3E are schematic sectional views showing a process for manufacturing a semiconductor device 200 according to a comparative example. For instance, as shown in FIG. 3A, contact plugs 53 and 55 are formed in the interlayer insulating film 40.

As shown in FIG. 3B, an insulating film 45 is formed to cover the interlayer insulating film 40 and the contact plugs 53, 55. The insulating film 45 is e.g. a silicon nitride film formed by CVD. Next, a sacrificial film 91 is formed on the insulating film 45. The sacrificial film 91 is e.g. a silicon oxide film.

As shown in FIG. 3C, interconnect grooves 93, 95, and 97 are formed by selectively removing the sacrificial film 91 and the insulating film 45. For instance, the interconnect groove 93 is formed in the memory area. The interconnect grooves 95, 97 are formed around the memory area. The interconnect groove 95 is formed so that the contact plug 53 is exposed at the bottom surface thereof.

As shown in FIG. 3D, a metal layer is buried inside the interconnect grooves 93, 95, and 97 to form bit lines 30 and interconnects 35, 37. The bit lines 30 and the interconnects 35, 37 include a barrier layer 31 and a conductive layer 33.

As shown in FIG. 3E, the sacrificial film 91 is selectively removed. Also in this example, a gap 103 having a uniform depth can be formed between the adjacent bit lines 30 by causing the insulating film 45 to function as an etching stopper.

However, the upper surface of the insulating film 45 is located at a level above the lower end of the bit line 30. Thus, the Z-direction width D₂ of the gap 103 is narrower than the spacing between the upper end and the lower end of the bit line 30. Accordingly, the effect of the gap 103 for reducing parasitic capacitance between the bit lines 30 is less than that of the gap 71 having a Z-direction width D₁ (>D₂). Furthermore, in the case where the insulating film 45 is a silicon nitride film, its permittivity is larger than the permittivity of the interlayer insulating film 40 made of silicon oxide film. This further decreases the effect for reducing the capacitance between the interconnects.

That is, in the embodiment, the upper surface of the insulating film 43 directly below the gap 71 is placed at the same level as the lower end of the bit line 30a and the lower end of the bit line 30b. This can reduce interconnect capacitance between the bit lines 30. Thus, for instance, the operating speed of the semiconductor device 100 can be improved.

### Second Embodiment

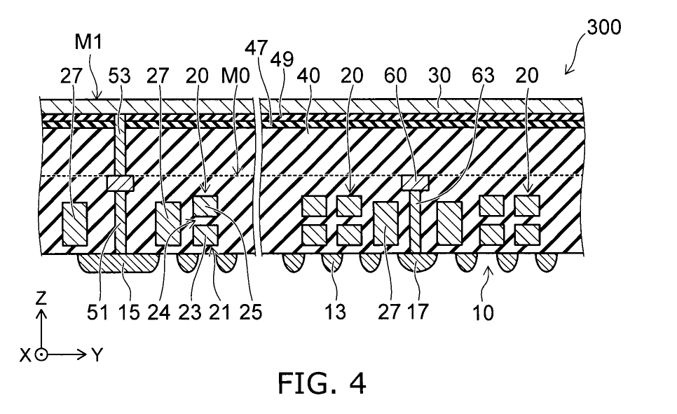

FIG. 4 is a schematic sectional view showing a semiconductor device 300 according to a second embodiment.

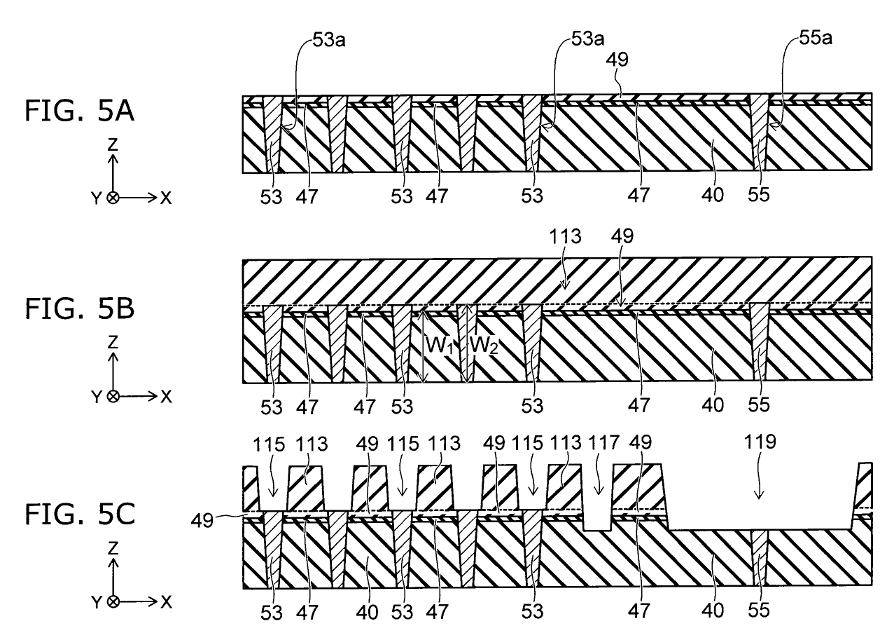

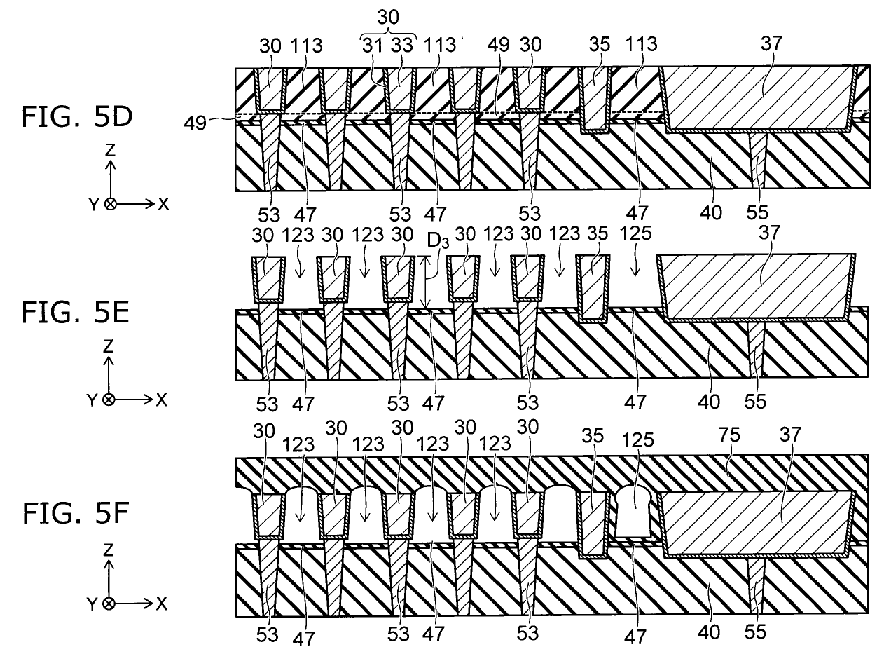

FIGS. 5A to 5E are schematic sectional views showing a process for manufacturing the semiconductor device 300 according to the second embodiment.

The semiconductor device 300 is e.g. a NAND flash memory. As shown in FIG. 4, the semiconductor device 300 includes a semiconductor layer 10, a plurality of memory cells 20 provided on the semiconductor layer 10, and a select gate 27.

The semiconductor device 300 further includes an interlayer insulating film 40, an insulating film 47, and an insulating film 49. The interlayer insulating film 40 covers the memory cells 20 and the select gate 27. The insulating film 47 is provided on the interlayer insulating film 40. The insulating film 49 is provided on the insulating film 47. A bit line 30 is provided on the insulating film 49 and extends in the Y-direction.

Next, a method for manufacturing the semiconductor device 100 is described with reference to FIGS. 5A to 5E. FIGS. 5A to 5E are schematic sectional views showing a process for forming the bit lines 30.

As shown in FIG. 5A, an insulating film 47 and an insulating film 49 are sequentially formed on the interlayer insulating film 40. The insulating film 47 is e.g. a silicon nitride film formed by CVD. The insulating film 49 is e.g. a silicon oxide film. Then, contact plugs 53 and 55 penetrating through the insulating film 49, the insulating film 47, and the interlayer insulating film 40 are formed. This can be based on e.g. the same process as the contact plugs 53 and 55 described with reference to FIG. 2A. A metal layer such as a tungsten layer covering the insulating film 49 is formed and buried inside the contact holes 53a and 55a. Next, the metal layer on the insulating film 49 is removed by CMP (chemical mechanical polishing). Thus, contact plugs 53 and 55 are formed inside the contact holes 53a and 55a. However, in contrast to the first embodiment described with reference to FIG. 2A, CMP stops at the insulating film 49.

As shown in FIG. 5B, a sacrificial film 113 is formed on the insulating film 49 to cover the contact plugs 53, 55. The sacrificial film 113 is e.g. a silicon oxide film.

As shown in FIG. 5C, interconnect grooves 115, 117, and 119 are formed by selectively removing the sacrificial film 113, the insulating film 49, and the insulating film 47. For instance, the interconnect groove 115 is formed in the memory area. The interconnect grooves 117, 119 are formed around the memory area. The interconnect groove 115 is formed so that the contact plug 53 is exposed at the bottom surface thereof.

As shown in FIG. 5D, a metal layer is buried inside the interconnect grooves 115, 117, and 119 to form bit lines 30 and interconnects 35, 37. The bit lines 30 and the interconnects 35, 37 include a barrier layer 31 and a conductive layer 33.

As shown in FIG. 5E, the sacrificial film 113 and the insulating film 49 are selectively removed. Also in this example, a gap 123 having a uniform depth can be formed between the adjacent bit lines 30 by causing the insulating film 47 to function as an etching stopper. Here, a gap 123 is formed also in the portion between the bit line 30 and the insulating film 47 where the contact plug 53 is not formed.

As shown in FIG. 5F, an insulating film 75 is formed on the bit lines 30 and the interconnects 35 and 37. The insulating film 75 is formed so as to occlude the top of the gap 123 between the adjacent bit lines 30 and a gap 125 between the interconnect 35 and the interconnect 37. The insulating film 70 is e.g. a silicon oxide film formed by plasma CVD (plasma enhanced chemical vapor deposition). The gap 123 extends in e.g. the Y-direction.

In the embodiment, the upper surface of the insulating film 47 is located at a level below the lower end of the bit line 30. The gap 123 can be formed so that its bottom surface is located at a level below the lower end of the bit line 30. Thus, the Z-direction width D₃ of the gap 103 can be made wider than the spacing between the upper end and the lower end of the bit line 30. This can further reduce parasitic capacitance between the bit lines 30.

In this example, CMP is stopped at the insulating film 49 in the process for forming the contact plugs 53 and 55 (see FIG. 5A). For instance, in the case of stopping CMP at a silicon nitride film, irregularities are likely to occur at its surface. Thus, the depth of the gap between the bit lines 30 is made nonuniform. This may degrade the characteristics of the semiconductor device. In the embodiment, CMP is stopped at the insulating film 49 (i.e., silicon oxide film). Thus, its surface can be made uniform. This can avoid the degradation of the characteristics of the semiconductor device.

It is understood that the interconnect structure and its manufacturing method illustrated in the first embodiment and the second embodiment are not limited to a NAND semiconductor memory device, but are also applicable to the interconnect of other semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor layer;
a first insulating film provided on the semiconductor layer;
a second insulating film provided on the first insulating film and including a material different from a material of the first insulating film;
a first interconnect extending in a first direction along a surface of the semiconductor layer on the second insulating film;
a second interconnect disposed side by side with the first interconnect on the second insulating film; and
a third insulating film covering the first interconnect and the second interconnect, the third insulating film including a first gap between the first interconnect and the second interconnect,
an upper surface of the second insulating film directly below the first gap being located at a level equal to or below a lower end of the first interconnect and a lower end of the second interconnect.

2. The device according to claim 1, wherein the first gap extends between the first interconnect and the second insulating film.

3. The device according to claim 2, wherein the first gap has a bottom surface located at a level below the lower end of the first interconnect and the lower end of the second interconnect.

4. The device according to claim 1, wherein
the first insulating film is a silicon oxide film, and
the second insulating film is a silicon nitride film.

5. The device according to claim 1, further comprising:
a conductor extending through the first insulating film and the second insulating film, the conductor electrically connecting the first interconnect to the semiconductor layer.

6. The device according to claim 1, wherein the gap extends in the first direction along the first interconnect and the second interconnect.

7. The device according to claim 1, further comprising:
a third interconnect disposed side by side with the second interconnect and extending in the first direction along the surface of the semiconductor layer on the second insulating film,
wherein the third insulating film covers the second interconnect and the third interconnect and includes a second gap between the second interconnect and the third interconnect; and
the upper surface of the second insulating film directly below the first gap is located at a level equal to an upper surface of the second insulating film directly below the second gap.

8. The device according to claim 1, further comprising:
a plurality of memory cells disposed side by side in the first direction on the semiconductor layer,
wherein the first insulating film covers the plurality of memory cells.

9. A method for manufacturing a semiconductor device, comprising:
forming a first insulating film on a semiconductor layer;
forming contact holes in the first insulating film;
burying a conductor in each of the contact holes;
selectively forming a second insulating film on a surface of the first insulating film;
forming a sacrificial film covering the second insulating film and the conductor;
selectively removing the sacrificial film to form a plurality of interconnect grooves extending in a first direction along a surface of the semiconductor layer, wherein the plurality of interconnect grooves include a first interconnect groove and a second interconnect groove adjacent to the first interconnect groove, and the conductor is exposed at each bottom surface of the first interconnect groove and the second interconnect groove;
forming a first interconnect in the first interconnect groove and a second interconnect in the second interconnect groove;
removing the sacrificial film between the first interconnect and the second interconnect to expose the second insulating film; and
forming a third insulating film bridging the first interconnect and the second interconnect over a gap between the first interconnect and the second interconnect.

10. The method according to claim 9, wherein
the first insulating film is a silicon oxide film, and
the second insulating film is formed by nitridizing the surface of the first insulating film.

11. The method according to claim 9, wherein the sacrificial film is removed under an etching condition such that an etching rate of the sacrificial film is faster than an etching rate of the second insulating film.

12. The method according to claim 9, wherein the third insulating film is formed to bridge the first interconnect and the second interconnect under a growth condition not burying a space between the first interconnect and the second interconnect.

13. A method for manufacturing a semiconductor device, comprising:
forming a first insulating film, a second insulating film including a material different from a material of the first insulating film, and a third insulating film layer in order on a semiconductor;
forming contact holes extending through the third insulating film, the second insulating film, and the first insulating film;
burying a conductor in each of the contact holes;
forming a sacrificial film on the third insulating film and on the conductor;
selectively removing the sacrificial film and the third insulating film to form a plurality of interconnect grooves extending in a first direction along a surface of the semiconductor layer, wherein the plurality of interconnect grooves include a first interconnect groove and a second interconnect groove adjacent to the first interconnect groove, and the conductor is exposed at each bottom surface of the first interconnect groove and the second interconnect groove;
forming a first interconnect in the first groove and a second interconnect in the second interconnect groove;
removing the sacrificial film between the first interconnect and the second interconnect, and the third insulating film directly below the sacrificial film to expose the second insulating film; and
forming a fourth insulating film bridging the first interconnect and the second interconnect over a gap between the first interconnect and the second interconnect.

14. The method according to claim 13, wherein
the second insulating film is a silicon nitride film, and
the third insulating film and the sacrificial film are silicon oxide films.

15. The method according to claim 13, wherein the third insulating film and the sacrificial film are removed under an etching condition where the third insulating film and the sacrificial film is removed with an etching rate faster than an etching rate of the second insulating film.

16. The method according to claim 13, wherein the step of burying the conductor in each of the contact holes comprising:
forming a conductive layer covering the third insulating film and being buried in the contact holes; and
polishing the conductive layer on the third insulating film until a surface of the third insulating film is exposed.
